(19) United States
(12) Patent Application Publication
(10) Pub. No.: US 2003/0128605 A1
(43) Pub. Date: Jul. 10, 2003

(54) Method of making identification code of ROM and structure thereof

(76) Inventors: Wen-Ying Wen, Hsinchu (TW); Nai-Tsung Hsu, Hsinchu (TW)

Correspondence Address: ROSENBERG, KLEIN & LEE, SUITE 101, 3458 ELLICOTT CENTER DRIVE, ELLICOTT CITY, MD, 21043, US

(21) Appl. No.: 10/370,767

(22) Filed: Feb. 24, 2003

Related U.S. Application Data
(62) Division of application No. 10/005,103, filed on Dec. 7, 2001.

(51) Int. Cl. G11C 7/00

(52) U.S. Cl. 365/200

(57) ABSTRACT

The present invention provides a method of making an ID code of ROM and a structure thereof, wherein an ROM code is implanted into channel regions between a plurality of bit lines and the region covered by a plurality of word lines on a semiconductor substrate. A field oxide for marking is situated at a predetermined position of the semiconductor substrate. A mark layer is attached on the surface of the field oxide using material different from oxide. The mark layer has a set of mark numbers to form an ID code structure. The formed ID code of the present invention can be clearly identified.

### FIELD OF THE INVENTION

The present invention relates to a technique of forming an identification code (ID code) of ROM code implanted in a memory on the surface of an oxide and, more particularly, to a method of making ID code of ROM with material different from oxide and a structure thereof.

### BACKGROUND OF THE INVENTION

In a general ROM, field effect transistors are used as memory cells, and the memory cells are arranged in arrays in the memory. Each combination of a column and a row represents a specific address of memory cell. Speaking in more detail, commonly used ROMs use channel transistors as memory cells, and a ROM code is selectively implanted into a specified channel region during the programming procedure so that on or off states of memory cells can be controlled by varying the threshold voltage (Vt).

A ROM is fabricated through many cycles of primary procedures such as deposition, photolithography, etching, and implantation. When fabricating a ROM, a basic device (including an implanted ROM code) is first formed on the surface of a silicon substrate. Subsequent procedures such as etching and implantation are then performed. Polysilicon word lines stride bit lines in the finished ROM structure. Channel regions of memory cells are situated between the bit lines and the region covered by the word lines to selectively implant ions into surfaces of the channel regions during the programming procedure so as to vary the amount and distribution of ions of the channel regions, thereby adjusting the threshold voltage to store data.

After implanting the ROM code, in order to know the implanted ROM code during subsequent procedures, a field oxide is generally used as a mark layer of ID code to etch the surface of the field oxide so as to form the ID code of the ROM code. However, for this kind of method of etching the field oxide to directly form the ID code of the ROM code, the ID code may easily abrade or be partly etched due to influence of planarization or etching during the subsequent metallization procedure; or the ID code may be completely covered by a dielectric layer so that it cannot be identified. For instance, in the disclosure of ROC Pat. No. 242,700, after first impurity is implanted, a buffer layer on a mark layer is directly etched to form an ID code on the mark layer. However, this prior art has the drawback that the ID code may be covered by a dielectric layer or may be damaged during subsequent procedures.

Accordingly, the present invention aims to propose a new structure of ID code different from the conventional structure and a method for making same to resolve the problems in the prior art.

### SUMMARY OF THE INVENTION

The primary object of the present invention is to propose a method of making ID code of ROM and a structure thereof, whereby the formed ID code can be clearly identified.

Another object of the present invention is to fabricate an ID code structure using material different from oxide to achieve the object of identifying the ID code directly through a microscope with the help of index difference.

To achieve the above objects, the present invention first provides a semiconductor substrate with a plurality of alternate bit lines formed thereon. A dielectric layer is then deposited. Next, a plurality of polysilicon word lines are formed on the dielectric layer to stride the bit lines. A field oxide for marking is disposed at a predetermined position of the semiconductor substrate. ROM codes are implanted into channel regions between the bit lines and the region covered by the polysilicon word lines. A set of ID numbers are formed by etching the surface of the field oxide so that the mark layer deposited on the semiconductor substrate can directly form a mark number identical to the ID number. Finally, the mark layer having the mark number is reserved to form an ID code structure.

The various objects and advantages of the present invention will be more readily understood from the following detailed description when read in conjunction with the appended drawing, in which:

### BRIEF DESCRIPTION OF THE DRAWINGS

FIG. 1A is a top view of a ROM of the present invention;

FIG. 1B is a cross-sectional view of FIG. 1A along line I-I; and

FIGS. 2A to 2E are cross-sectional views of the flowchart of making an ID code of ROM according to a preferred embodiment of the present invention.

### DETAILED DESCRIPTION OF THE PREFERRED EMBODIMENTS

The present invention fabricates an ID code structure using material different from oxide on the surface of a field oxide. Through the ID code structure of different material, the formed ID code can be easily and clearly identified and will not be affected by another cover layer (dielectric layer).

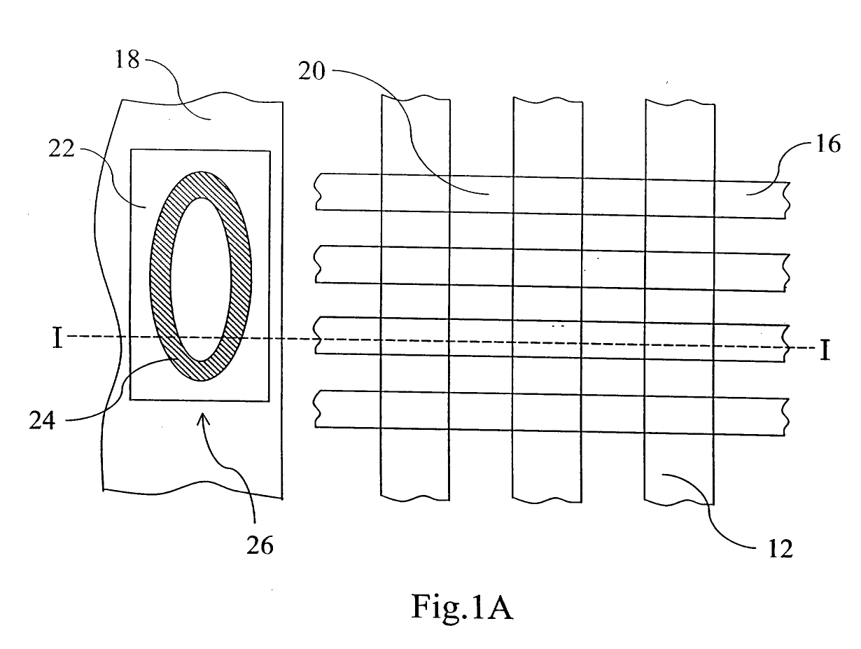

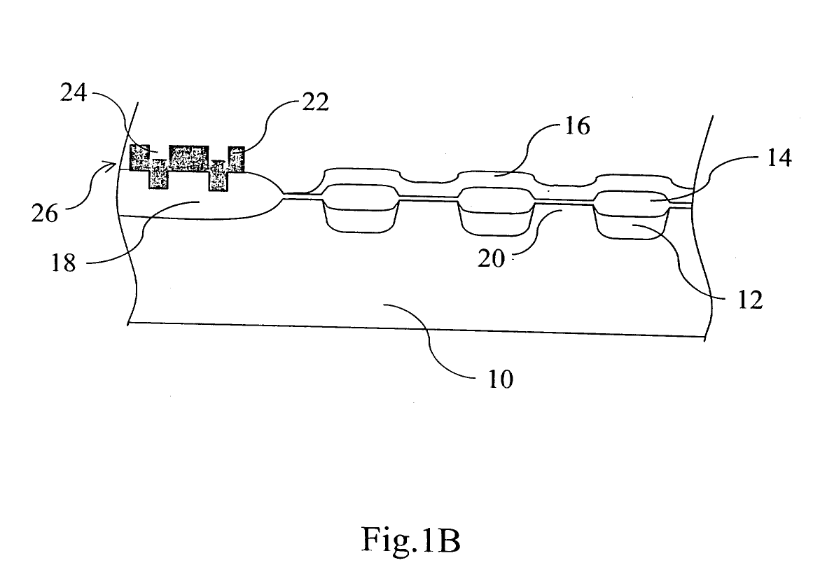

As shown in FIGS. 1A and 1B, a plurality of alternate bit lines 12 are formed on a semiconductor substrate 10. A dielectric layer 14 covers the bit lines 12. A plurality of polysilicon word lines 16 are then formed on the dielectric layer 14 to stride the bit lines 12. A field oxide 18 for marking is situated at a predetermined position of the semiconductor substrate 10. Ion implantation is utilized to implant a ROM code into channel regions 20 between the bit lines 12 and the region covered by the word lines 16. A metal mark layer 22 is situated on the surface of the field oxide. Similarly, an ID code is implanted into the field oxide 18. An ID number 30 is formed during the subsequent etching procedure to form an ID code structure 26.

The above metal mark layer 22 can be made of other material different from oxide such as polysilicon and nitride. A plurality of metal interconnects and dielectric layers (not shown) for isolating metal layers are further formed above the semiconductor substrate 10.

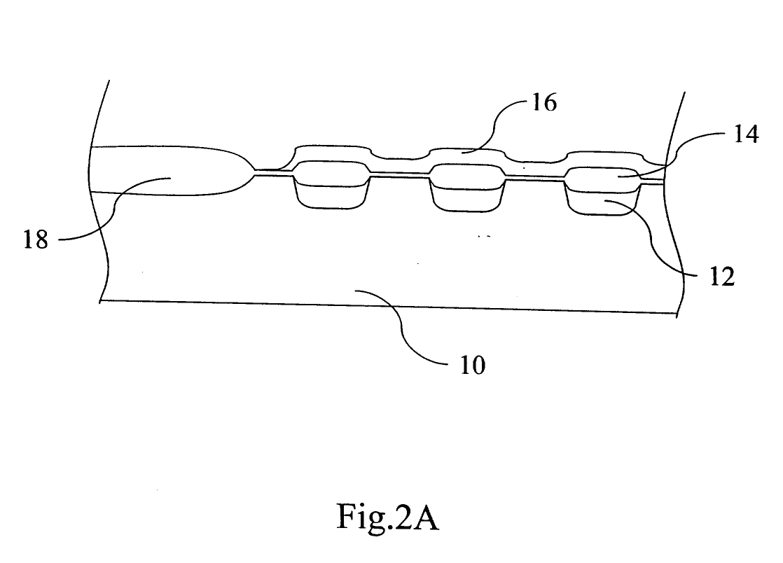

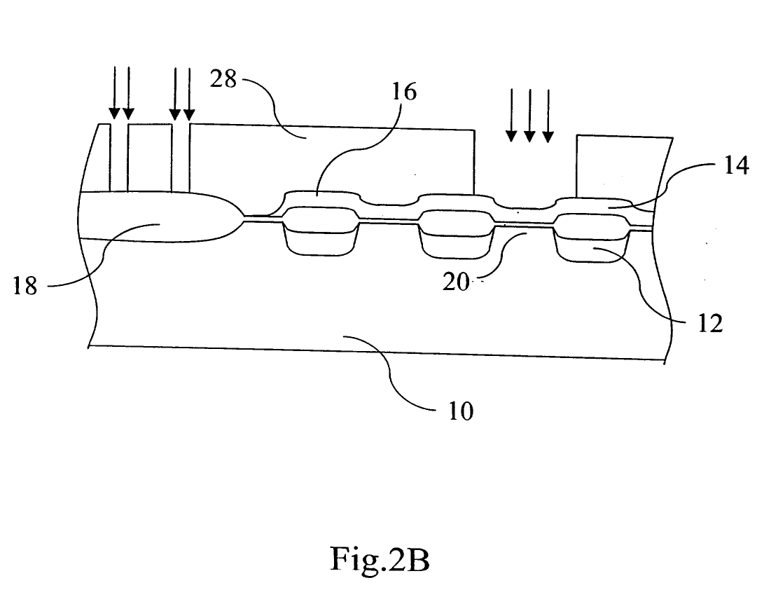

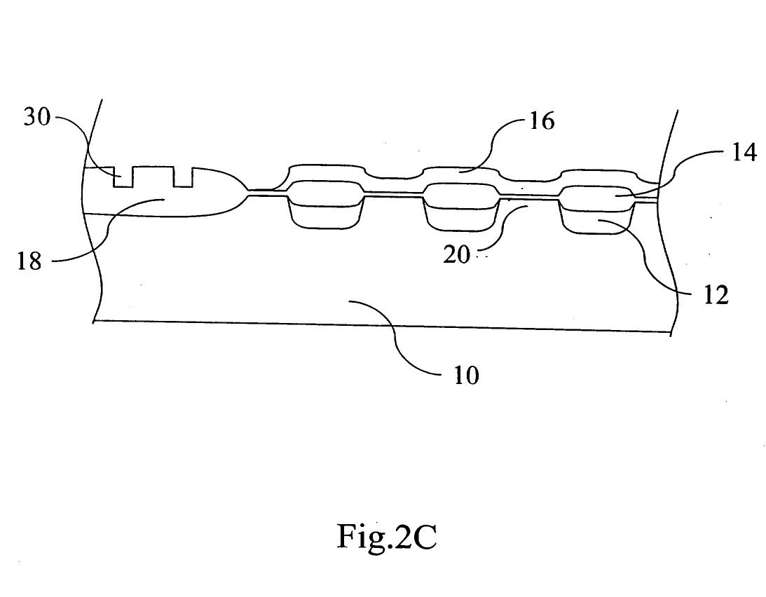

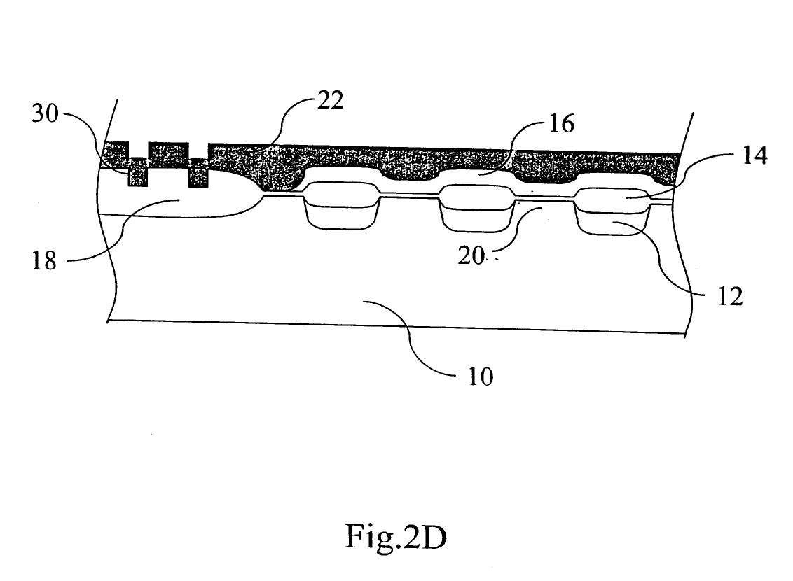

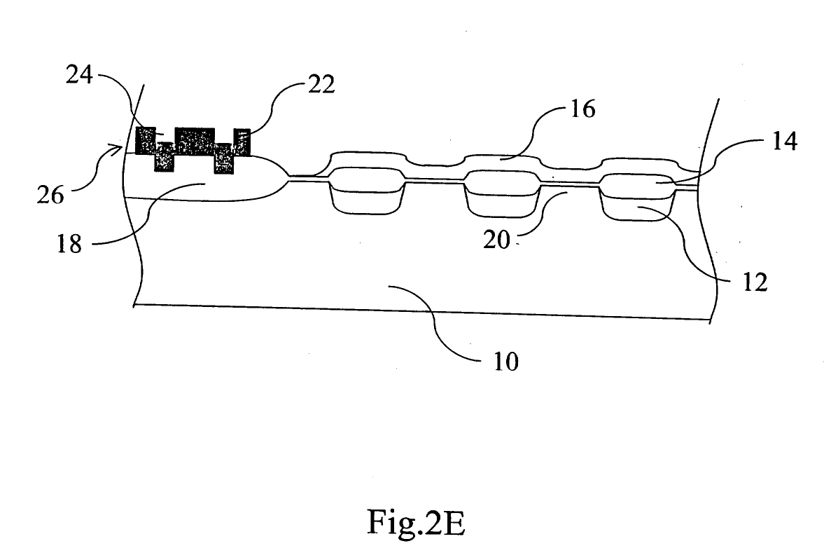

As shown in FIGS. 2A to 2E, the fabrication method of the present invention comprises the following steps.

First, as shown in FIG. 2A, a semiconductor substrate 10 is provided. A plurality of alternate bit lines 12 are formed on the semiconductor substrate 10. A dielectric layer is also deposited. A plurality of polysilicon word lines 16 are then formed on the dielectric layer 14 to stride the bit lines 12. A field oxide 18 for marking is disposed at a predetermined position of a side of the semiconductor substrate 10.

Next, photolithography and etching are performed. Yellow-light photolithography is utilized to form a patterned photoresist layer 28 above the semiconductor substrate 10, as shown in FIG. 2B. Ion implantation is performed to channel regions between the bit lines 12 and the region covered by the polysilicon word lines 16 with this patterned photoresist layer 28 as a mask to implant an ROM code. Simultaneously, an ID code is implanted into the field oxide 18.

Subsequently, as shown in FIG. 2C, etching technique is utilized to etch a set of recessed ID numbers 30 on the surface of the field oxide 18. The photoresist layer 28 is then removed.

Afterwards, as shown in FIG. 2D, a metal mark layer 22 is then deposited on the semiconductor substrate 10 to cover the polysilicon word lines 16 and the field oxide 18. Metal material of the metal mark layer 22 will fill the recessed ID numbers 30 in the field oxide 18 to automatically form a mark number 24 identical to the ID number 30 on the metal mark layer 22 on the field oxide 18.

Finally, the metal mark layer 22 not required is removed, and the metal mark layer 22 having the mark number 24 on the field oxide 18 is reserved, as shown in FIG. 2E. An ID code structure 26 capable of being easily identified is thus formed.

After forming the ID code structure 26, subsequent metallization procedure can further be performed to form multi-layer metal interconnects and dielectric layers for isolating metal layers on the semiconductor substrate. If the dielectric layer situated above the ID code structure is too deep, a window can be formed by etching the dielectric layer of the multi-layer metal interconnects on the ID code structure to expose the ID code structure.

The present invention fabricates an ID code structure on the surface of a field oxide with material different from oxide. The object of identifying the ID code directly through a microscope with the help index difference can be achieved even if a plurality of dielectric layers or oxides are stacked thereon. Therefore, the present invention can obtain a clear ID code structure and the required ID code of ROM code can also be acquired by means of a simpler ID way or apparatus.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore all such substitutions and modifications are intended to be embraced within the scope of the invention as defined in the appended claims.

I claim:

1. A method of making an ID code of ROM, comprising the steps of:
providing a semiconductor substrate with a plurality of alternate bit lines formed thereon forming a dielectric layer, forming a plurality of word lines on said dielectric layer to stride said bit lines, disposing a field oxide for marking at a predetermined position of a side of said semiconductor substrate;
implanting a ROM code into channel regions between said bit lines and the region covered by said word lines;
forming a set of ID numbers by etching a surface of said field oxide;
depositing a mark layer on said semiconductor substrate, directly forming a mark number identical to said ID number on said mark layer on said field oxide; and
removing said mark layer not required, reserving said mark number on said field oxide to form an ID code structure.

2. The method as claimed in claim 1, wherein subsequent metallization procedure can further be performed to form multi-layer metal interconnects on said semiconductor substrate after forming said ID code structure.

3. The method as claimed in claim 2, wherein a window can further be formed on said multi-layer metal interconnects on said ID code structure to expose said ID code structure.

4. The method as claimed in claim 1, wherein the material of said mark layer can be selected among the group composed of metal, polysilicon, nitride, and other materials different from oxide.

5. The method as claimed in claim 1, wherein said word lines are polysilicon word lines.

6. A method of making an ID code of ROM, comprising the steps of:
providing a semiconductor substrate with a plurality of alternate bit lines formed thereon, forming a dielectric layer, forming a plurality of word lines on said dielectric layer to stride said bit lines, disposing a field oxide for marking at a predetermined position of a side of said semiconductor substrate;
implanting a ROM code into channel regions between said bit lines and the region covered by said word lines; and
forming a mark layer having an ID number on a surface of said field oxide to obtain an ID code structure.

7. The method as claimed in claim 6, wherein subsequent metallization procedure can further be performed to form multi-layer metal interconnects on said semiconductor substrate after forming said ID code structure.

8. The method as claimed in claim 7, wherein a window can further be formed on said multi-layer metal interconnects on said ID code structure to expose said ID code structure.

9. The method as claimed in claim 6, wherein the material of said mark layer can be selected among the group composed of metal, polysilicon, nitride, and other materials different from oxide.

10. The method as claimed in claim 6, wherein said word lines are polysilicon word lines.

11. An ID code structure of ROM, comprising:
a semiconductor substrate with a plurality of alternate bit lines and a dielectric layer covering said bit lines formed thereon, a plurality of bit word lines being formed on said dielectric layer to stride said bit lines, a field oxide for marking being disposed at a predetermined position of said semiconductor substrate;
a ROM code implanted into channel regions between said bit lines and the region covered by said word lines; and
a mark layer situated on said field oxide, a mark number being formed by etching a surface of said mark layer to form an ID code structure.

12. The ID code structure as claimed in claim 11, wherein multi-layer metal interconnects and dielectric layers for isolating metal layers are formed on said semiconductor substrate.

13. The ID code structure as claimed in claim 12, wherein a window is formed on said dielectric layer of said multi-layer metal interconnects on said ID code structure to expose said ID code structure.

14. The ID code structure as claimed in claim 11, wherein the material of said mark layer is selected among the group composed of metal, polysilicon, nitride, and other materials different from oxide.

15. The ID code structure as claimed in claim 11, wherein said word lines are polysilicon word lines.
